(19) United States
(12) Patent Application Publication
(10) Pub. No.: US 2018/0205198 A1
(43) Pub. Date: Jul. 19, 2018

(54) Optical Test System Using an Array Laser

(71) Applicant: Stephen Frank Blazo, Corvallis, OR (US)

(72) Inventor: Stephen Frank Blazo, Corvallis, OR (US)

(73) Assignee: Stephen Blazo, Corvallis, OR (US)

(21) Appl. No.: 15/410,229

(22) Filed: Jan. 19, 2017

(51) Int. Cl. H01S 5/06; H01S 5/40; H01S 5/0687; H01S 5/024

(52) U.S. Cl. CPC H01S 5/0612; H01S 5/4012; H01S 5/02415; H01S 5/0687; H01S 5/4087

(57) ABSTRACT

A scheme which uses a laser array and means of generating accurate wavelength fiducial markers to scan a wide wavelength range. The scan of each laser chip overlaps the adjacent chip and this overlap region contains at least one fiducial mark. The clock used for data collection and that used to generate the fiducial marks is derived from the same source.

### BACKGROUND

An accurate tunable fiber based laser has many applications. One application with a high volume is to provide spares for WDM (wavelength division multiplexing) optical networks where one laser fails. A WDM network may have 100 separate channels on a single line each spaced in frequency by 50 GHz. The standard laser for this application is a semiconductor DFB (distributed feedback) laser. This technology generates a very narrow high power output very suitable for the network. The output wavelength of this laser can be tuned a few nm by changing the chip temperature but this is only a portion of the required wavelength range. A widely tunable laser would solve this problem. In response to this need Fitel has developed an array of DFB lasers in one package, the FRL15TCW. Note that this is a quasi-static application since the laser just goes to the desired location and sits there. There are 12 laser chips in this package each tunable over about a 3.5 nm range so a total wavelength range of 35 nm is available.

There are also several applications where laser with a wide wavelength span that is swept over this range is needed. Here there is usually a data collection system where the response of a device over a range of wavelengths is needed. One such application is for a fiber Bragg grating sensing system. Here we have a fiber with one or several Fiber Bragg gratings. A laser illuminates the fiber and its wavelength swept. Each grating reflects a specific wavelength which depends on the state of the device under test (DUT). The test point may be some distance from the interrogator. This application tends to be very sensitive to cost and for field use a high level of robustness is required. Another application would be the stimulus response testing of optical components. Here the application requires very high accuracy but cost is still an issue. Therefore a low cost rugged laser that can combine a large wavelength span coupled with data acquisition that can accurately identify each data point with a particular wavelength is needed.

One previous solution is the N7700A from Keysight Technologies. This application combines external cavity tunable laser with a high speed optical power meter and an application suite. The performance of this solution is high but cost of this system is >$100,000. Another shortcoming is the fact that wavelength tuning is done by mechanical means which are sensitive to shock and vibration and less reliable then means not using mechanical tuning.

Another solution used for fiber Bragg grating interrogator is the Micron Optics S3. The S3 uses a tunable ring laser to interrogate a fiber Bragg grating sensor array. The ring laser consists of a length of erbium doped fiber acting as the gain medium in series with a tunable filter. The output is then fed back to the input. The useful output is split off the ring. Due to the length of the optical resonator which allows many longitudinal modes to operate the laser is multimode. Therefore the spectral width of this laser is about 150 pm as compared to <1 pm for a DFB laser. The system uses a gas cell to calibrate the sweep. This solution can have high accuracy due to the presence of the gas cell but is still costly and the laser output has limited spectral resolution compared to a standard DFB laser.

The distributed Bragg reflection sampled grating diode laser is used by Insight Photonics. This technology uses wavelength tunable reflectors and phase shifting elements to achieve wavelength tuning of a single laser chip. The tuning mechanism is quite complex and exhibits continuous tuning over many small regions. U.S. Pat. No. 9,455,549 B2 demonstrates one embodiment. As is shown in the patent at the boundaries of one monotonic tuning region the tuning exhibits step changes to the tuning voltages and optical artifacts are generated. There are many such boundaries for a laser tunable over the entire C-band.

What is needed is a rugged system which can generate a broad wavelength sweep and take data on the devices under test where each data point is referenced to a precise wavelength and at a low cost.

### BRIEF SUMMERY

To generate an accurate widely tunable laser the present invention uses an array of laser chips each tunable over a small scan. To output a given wavelength the appropriate chip is activated and the chip tuned to the correct wavelength. Fitel sells such a product the FRL15TCW. With 12 laser chips in one package this results in a large 35 nm total tuning range. The tuning mechanism is the combination of laser choice and the chip temperature. The individual laser chips are typically distributed feedback or DFB lasers. This basic laser technology is well known with >100000 lasers in operation and produces an output with a narrow clean spectrum. The large volume applications results in a very low comparative cost for such a high technology component. The temperature tuning mechanism is slow with tuning over the 3 nm region of each chip taking on the order of 3 seconds. If the lasers were tuned separately this would give a total sweep time of over 30 seconds. The selection time to turn off one laser and turn on another and take data samples can be much faster than the temperature tuning. To minimize sweep time the present invention takes data using all lasers turned on sequentially at each point on the temperature sweep. This allows a complete data set in the time for one temperature sweep. During the sweep we pass part of the output through a wavelength monitor. The wavelength monitor, generally an etalon, generates markers at specific wavelengths. We interpolate to get data at wavelengths between the markers. Since the temperature tuning is quite smooth we need only a few markers to achieve high accuracy at all wavelengths. The temperature sweeps are designed so that the sweep record of one laser will overlap a part of the adjacent laser's record. With at least one marker common to records of adjacent lasers the entire wavelength scan can be produced by splicing the data sets together.

### FIGURES

FIG. 1 shows a block diagram of my invention

FIG. 2 illustrates how the records from all the lasers is combined to one data set

### DETAILED DESCRIPTION

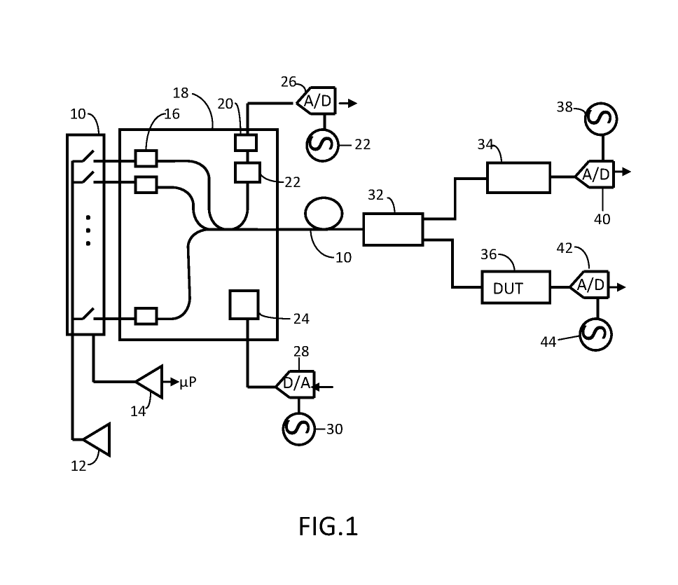

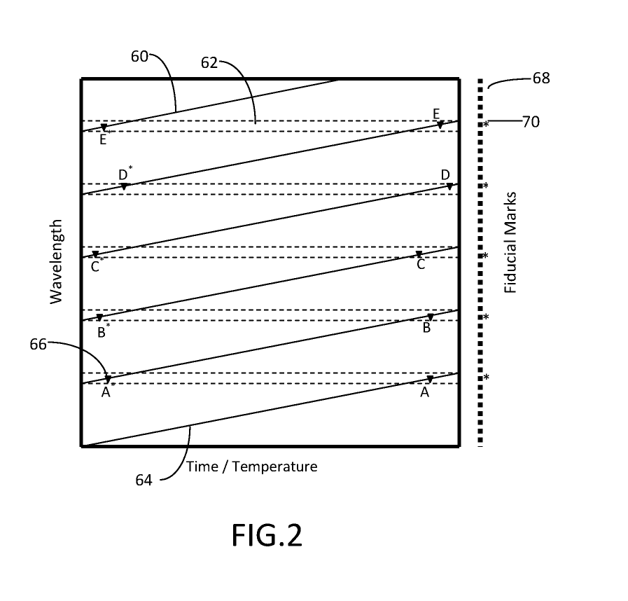

For a preferred embodiment refer to FIG. 1. The laser array 18 generates a laser output whose wavelength is determined by the choice of laser chip 16 activated and the temperature of the laser chip. All the chips outputs are combined into one signal. The choice of laser activated is set by switch 10. The switch state is determined by the microprocessor and switch drive 14. The level of laser drive is set by amplifier 12. The chip temperature is determined by the drive to the TE cooler 20. The TE cooler drive is set by a D/A convertor 28 under control of a microprocessor to produce the wavelength sweep. The clock source for the D/A 30 in most cases will be the same as A/Ds 30, 38, and 44 but this is not necessary. If we scan the TE cooler drive each laser chip will span a wavelength range typically about 3.5 nm over a temperature range of 40 degC. The sweep of the TE cooler is designed so as to allow a certain overlap in wavelength scans of the adjacent laser(s) as shown in FIG. 2 62. The use of temperature to scan the wavelength while inherently slow has the advantage that it results in a smooth reproducible wavelength scan without mode hop jumps or other optical artifacts. This is advantageous since between known accurate wavelength markers we interpolate the data points. The interpolation process is easiest if the wavelength sweep is smooth and if possible linear. Accurate interpolation is still possible for a nonlinear sweep so long as the shape is reproducible. If this is still an issue the D/A sweep can be distorted so that the resultant wavelength sweep is nearly linear.

To calibrate the wavelength scan known wavelength markers are used. A part of the laser output is split internal to the laser package to an etalon 22 and converted to an electrical signal by photodiode 20. This is shown to be digitized by A/D convertor 26. The etalon has a free spectral range of 50 GHz so that markers can be determined at 25 GHz intervals one for the peak and one for a valley. The etalon should have sufficiently small free spectral range so as to generate enough markers for interpolation but not so many as to cause identifying a specific marker in adjacent lasers overlap scan difficult. A part of the output signal is split by optical splitter 32 and fed into a gas cell 34 and digitized by A/D convertor 40. The rest of the output is available for probing the device or devices under test 36. It is critical that the clock sources 22, 40, and 44 be derived from the same master clock. The data taken is shown from A/D convertors. In many cases the required data can be derived from a comparator instead of an A/D convertor. The markers generated by the etalon are not known as accurately as the gas cell absorption lines. To improve the accuracy the gas lines can be used to calibrate the etalon signal.

The temperature sweep of the laser chip is a slow process while the turn on and turn off of the individual lasers is very fast. The individual temperature sweeps take about 3 seconds. If we used a temperature sweep for each laser the update rate would be slow. To improve that as the temperature is incremented samples are taken from all the lasers in a round robin fashion at each temperature point. This results in a many times improvement in the total time taken to scan the full wavelength range.

The data extraction process is made clear by FIG. 2. The wavelength sweep of each laser 60, 64 is shown along with overlap regions 62. To extract a single record we note the wavelength markers common to adjacent lasers and splice the data at these points. So as shown the final record would be start, A A′, B B′, C C′, D D′, E E′ and so on. For samples taken between markers interpolation is used. So long as enough makers are used this gives sufficient accuracy. With the markers generated at 25 GHz we find that accuracy of <±10 MHz should be attainable.

1) Means of generating a laser output scan covering accurately a large wavelength span using multiple laser diode chips in a single package where the wavelength span of each laser diode overlaps the wavelength span of adjacent lasers along with a means of generating precise wavelength markers where the overlap region contains at least one fiducial mark common to another laser chip

2) The means of claim 1 where the marker means is a gas cell

3) The means of claim 1 where the marker means is a stable etalon

4) The means of claim 1 where the marker means is a combination of a gas cell and an etalon

5) The means of claim 1 where the wavelength span is generated by sweeping the temperature of the laser chips mount

6) The means of claims 1 where all the lasers are sequentially selected at each point of the temperature sweep
